(19) United States
(12) Patent Application Publication
(10) Pub. No.: US 2016/0190342 A1
(43) Pub. Date: Jun. 30, 2016

(54) ACTIVE ELEMENT AND FABRICATING METHOD THEREOF

(71) Applicant: Chunghwa Picture Tubes, LTD., Taoyuan City (TW)

(72) Inventors: Hao-Wei Wang, Pingtung County (TW); Chia-Ming Chiang, Taoyuan County (TW); Chih-Wen Lai, Nantou County (TW)

(21) Appl. No.: 14/662,041

(22) Filed: Mar. 18, 2015

(30) Foreign Application Priority Data
Dec. 27, 2014 (TW) 103145952

(51) Int. Cl. H01L 29/786; H01L 29/66

(52) U.S. Cl. CPC H01L 29/78663; H01L 29/6675

(57) ABSTRACT

An active element and a fabricating method thereof are provided. The active element includes a gate, a gate insulating layer, a channel, a source and a drain. The gate is disposed on a substrate. The gate insulating layer is disposed on the substrate and covers the gate. The gate insulating layer is divided into a first region having uniform thickness and a second region having uniform thickness. The thickness of the gate insulating layer in the first region is different from the thickness of the gate insulating layer in the second region. The channel is disposed on the gate insulating layer. The source and the drain are disposed on the gate insulating layer and separated from each other. The distribution region of the source and the drain is identical to the distribution region of the first region. The channel contacts with the source and the drain.

### CROSS-REFERENCE TO RELATED APPLICATION

This application claims the priority benefit of Taiwan application serial no. 103145952, filed on Dec. 27, 2014. The entirety of the above-mentioned patent application is hereby incorporated by reference herein and made a part of this specification.

### BACKGROUND OF THE INVENTION

1. Field of the Invention

The invention relates to an element and a fabricating method thereof, and relates particularly to an active element and a fabricating method thereof

2. Description of Related Art

Liquid Crystal Displays (LCDs) having superior characteristics such as high definition, good space utility factor, low power consumption and no radiation have already gradually become mainstream in the market. Generally speaking, an LCD includes an LCD panel and a backlight module for providing a surface light source, wherein the LCD panel typically includes a thin film transistor array substrate, a color filter substrate (CF substrate) and a liquid crystal layer located between two substrates.

FIG. 1 is a schematic diagram illustrating a circuit of a conventional pixel array substrate. Referring to FIG. 1, generally speaking, thin film transistors TFT_{10A}, TFT_{10B}, TFT_{10C} . . . of pixel structures P_{10A}, P_{10B}, P_{10C} . . . located on the same row of a pixel array substrate 10 are all driven by a same scan line S10. When the scan line S10 is provided with a sufficient turn-on voltage, the thin film transistors TFT_{10A}, TFT_{10B}, TFT_{10C} . . . connected to the scan line S10 will be opened, allowing the data (voltage level) carried by each data line D10 to be written to the pixel structures P_{10A}, P_{10B}, P_{10C} . . . After the above write action is completed, the thin film transistors TFT_{10A}, TFT_{10B}, TFT_{10C} . . . will be turned off, and the voltage level of a pixel electrode in each of the pixel structures P_{10A}, P_{10B}, P_{10C} . . . are kept by the LC capacitor C_{LC} and the pixel storage capacitor C_{ST} and the like.

However, when the thin film transistors TFT_{10A}, TFT_{10B}, TFT_{10C} . . . are turned off, the voltage level of the pixel electrode in each of the pixel structures P_{10A}, P_{10B}, P_{10C} . . . are easily affected by other surrounding voltage influences that change the voltage level and will thus fluctuate, and the amount of fluctuation in the voltage is referred to as the feed-through voltage, and is represented as ΔV_{P} below. The feed-through voltage ΔV_{P} may be expressed as:

ΔV_{P}=[C_{GD}/(C_{LC}+C_{ST}+C_{GD})]×ΔV_{G} (1)

The C_{LC} in equation (1) is the liquid crystal capacitance, the C_{ST} is the pixel storage capacitance and C_{GD} is the capacitance between the gate and the drain of the thin film transistor (TFT). ΔV_{G} is the voltage difference between when the scan line turns the TFT on and off. In the operation principles of an LCD, a variety of gray scale changes are exhibited mainly by the magnitude of an electric field applied to the liquid crystal molecules to change the rotation angle of the liquid crystal molecules. The magnitude of the electric field applied to the liquid crystal molecules is determined by the voltage difference between the pixel electrode of each pixel structure and a common electrode, and therefore when the voltage level of the pixel electrode fluctuates when affected by the feed-through voltage ΔV_{E}, then the display effects of the LCD will be influenced.

Generally speaking, the influence caused by the feed-through voltage ΔV_{P} may be eliminated by adjusting the voltage level of the common electrode. However, due to the influence from resistors and other capacitors in the scan line, the feed-through voltage ΔV_{P} becomes smaller, as the distance of the pixel structure becomes further from the scan line input end. Namely, as shown in FIG. 1, the ΔV_{P} of the pixel structures P_{10A}, P_{10B}, P_{10C} . . . will render a phenomenon where (ΔV_{P})A>(ΔV_{P})B>(ΔV_{P})C, and causing a flicker on the screen of the LCD.

### SUMMARY OF THE INVENTION

The invention provides an active element, which improves a problem caused by excessive feed-through voltage of conventional technology.

The invention provides a fabricating method of an active element, which improves a problem caused by excessive feed-through voltage in an active element fabricated by conventional technology.

An active element of the invention includes a gate, a gate insulating layer, a channel, a source and a drain. The gate is disposed on a substrate. The gate insulating layer is disposed on the substrate and covers the gate. The gate insulating layer is divided into a first region and a second region. The first region has a uniform thickness and the second region has a uniform thickness, and the thickness of the first region is greater than the thickness of the second region. The channel is disposed on the gate insulating layer. The source and the drain are respectively disposed on the gate insulating layer and separated from each other. A distribution region of the source and the drain is the same as a distribution region of the first region. The channel contacts the source and the drain.

In an embodiment of the invention the gate insulating layer includes a first insulating layer and a second insulating layer. The first insulating layer is located at the first region and the second region, and has a uniform thickness. The second insulating layer is located at the first region and has a uniform thickness.

In an embodiment of the invention a material of the first insulating layer is different from a material of the second insulating layer.

In an embodiment of the invention the gate insulating layer is construed of a single material.

In an embodiment of the invention the active element further includes a pixel electrode electrically connected with the drain.

In an embodiment of the invention a material of the channel is amorphous silicon.

A fabricating method of an active element of the invention includes the following steps. A gate is formed on a substrate. A gate insulating layer is formed on the substrate and covers the gate. The gate insulating layer is divided into a first region and a second region. The first region has a uniform thickness and the second region has a uniform thickness. The thickness of the first region is greater than the thickness of the second region. A channel, a source and a drain are formed on the gate insulating layer. The source and the drain are separated from each other, and a distribution region of the source and the drain is the same as a distribution region of the first region. The channel contacts the source and the drain.

In an embodiment of the invention, forming the gate insulating layer includes the steps below. A first insulating layer is formed at the first region and the second region. The first insulating layer has a uniform thickness. A second insulating layer is formed at the first region. The second insulating layer has a uniform thickness.

In an embodiment of the invention a photo mask used for forming the second insulating layer and a photo mask used for forming the source and the drain are the same.

In an embodiment of the invention the gate insulating layer is formed by a single photolithography process.

According to the above, in an active element and a fabrication method thereof of the invention, a thickness of a gate insulating layer underneath a source and a drain are increased to decrease a capacitance between a gate and the drain, and therefore a feed-through voltage of the active element may be decreased.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a circuit of a conventional pixel array substrate.

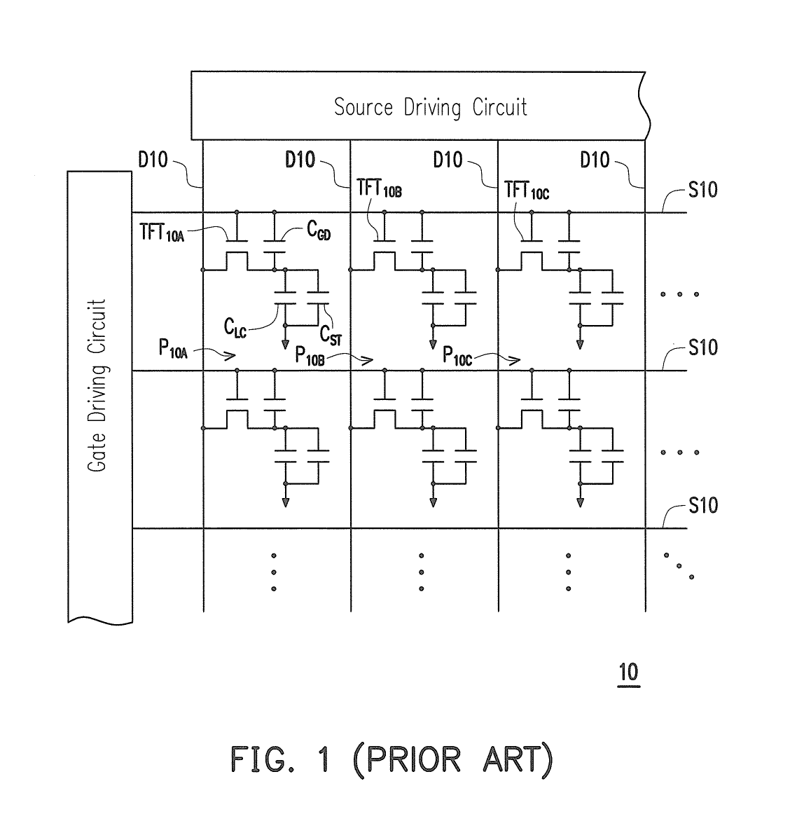

FIG. 2A to FIG. 2G are cross-sectional views illustrating a flow of a fabricating method of an active element according to an embodiment of the invention.

FIG. 3 is an analysis chart simulating a capacitance C_{GD} and the resolution of the display.

FIG. 4 is an analysis chart simulating a feed-through voltage ΔV_{P} and the resolution of the display.

FIG. 5 is a top schematic view of the active element of FIG. 2G.

FIG. 6 is a cross-sectional schematic view illustrating an active element according to an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

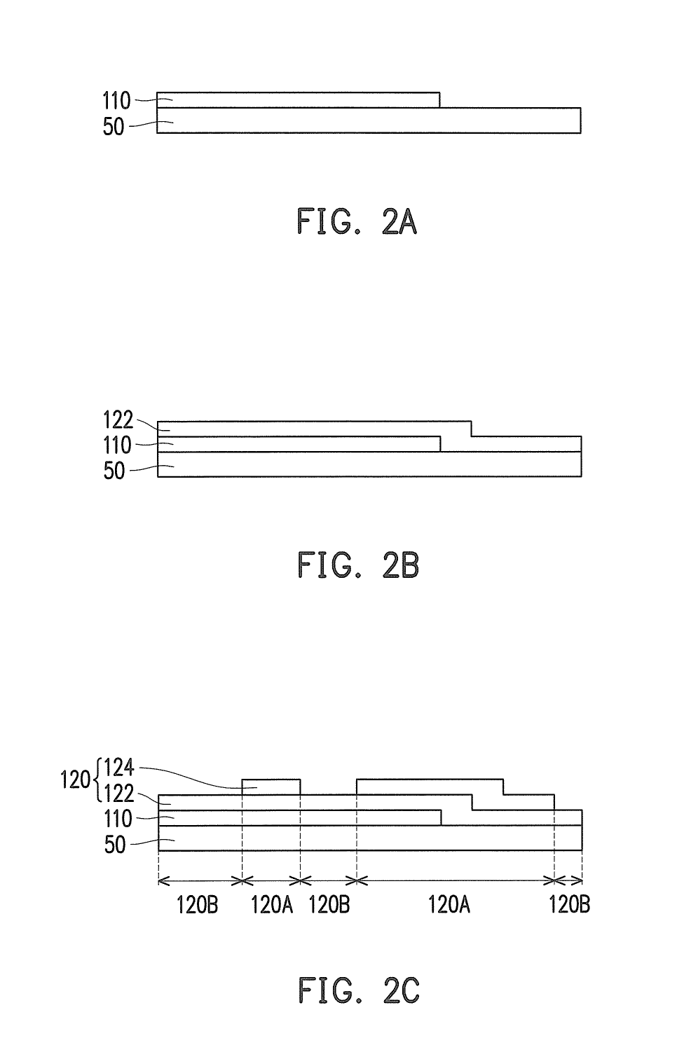

A fabricating method of an active element according to an embodiment of the invention is described as follows. First as shown in FIG. 2A, a gate 110 is formed on the substrate 50. A material of the substrate 50 may be glass, quartz, organic polymer, a light opaque/reflective material (for example, conductive material, wafer, ceramic and the like) or other suitable material. A material of the gate 110 typically is a metallic material. However the invention is not limited thereto, and in other embodiments, a material of the gate 110 may be other conductive materials such as an alloy, a metal nitride material, a metal oxide material, metal nitrogen oxide or a stacked layer of a metal material and other conductive material.

Referring to FIG. 2A and FIG. 2B, first as shown in FIG. 2B, a first insulating layer 122 is formed on the substrate 50 and covers the gate 110, and the first insulating layer 122 is distributed at both of a first region 120A and a second region 120B. The first insulating layer 122 has a uniform thickness. Next, as shown in FIG. 2C, a second insulating layer 124 is formed at the first region 120A. The second insulating layer 124 has a uniform thickness. A gate insulating layer 120 is formed on the substrate 50 and covers the gate 110. In other words, the gate insulating layer 120 of the present embodiment is construed by the first insulating layer 122 and the second insulating layer 124, however it should not be construed as a limitation to the invention. Basically, the gate insulating layer 120 covers the entire substrate 50, however it should not be construed as a limitation to the invention, and it only needs to cover the entire gate 110. The gate insulating layer 120 is divided into the first region 120A and the second region 120B. The first region 120A has a uniform thickness, and the second region 120B has a uniform thickness, and furthermore the thickness of the first region 120A is greater than the thickness of the second region 120B. In the present embodiment, the first region 120A is a combination of a plurality of separate regions, and the second region 120B is also a combination of a plurality of separate regions. The first region 120A having a uniform thickness refers to the thicknesses of the part of the gate insulating layer 120 at the first region 120A is basically the same, but does not rule out thickness differences due to error margins of the production process or other causes. This also applies to the second region 120B. It is noted here, using the gate insulating layer 120 of FIG. 2B as an example, the thickness of the first insulating layer 122 depicted at the edge of the gate 110 is thicker, but it is due to the representation method of the schematic and is not required. During real production of the first insulating layer 122, the thickness of the gate 110 at the edge may also have error margin. However, the first insulating layer 122 of the embodiment having a uniform thickness refers to an ideal design target. This is also applicable to the second insulating layer 124. Because the first insulating layer 122 and the second insulating layer 124 each have a uniform thickness, but the first insulating layer 122 is distributed both to the first region 120A and the second region 120B and the second insulating layer 124 is distributed only to the first region 120A, therefore the thickness of the gate insulating layer 120 at the first region 120A will be greater than the thickness of the gate insulating layer 120 at the second region 120B. A material of the first insulating layer 122 and the second insulating layer 124 may be selected from inorganic materials (silicon oxide, silicon nitride, silicon oxynitride, other suitable material or a stacked layer of at least to of the above types of material), organic materials or a combination of the above. A material of the first insulating layer 122 and the second insulating layer 124 may be the same or different.

Next, as shown in FIG. 2D, a channel 130 is formed on the gate insulating layer 120. The present embodiment may be used in a display device, and here as shown in FIG. 2E, a pixel electrode 140 may be selectively formed on the gate insulating layer 120. Next, as shown in FIG. 2F, a source 152 and a drain 154 are formed on the gate insulating layer 120, wherein the drain 154 contacts and is electrically connected with the pixel electrode 140. The source 152 and the drain 154 are separated from each other, and the channel 130 contacts the source 152 and the drain 154. At this point, the active element 100 of the present embodiment is roughly complete. In the present embodiment, the channel 130, the pixel electrode 140, the source 152 and the drain 154 are formed sequentially, however the order of formation may be adjusted according to requirements as long as the channel 130 contacts the source 152 and the drain 154, and the drain 154 is electrically connected with the pixel electrode 140.

In addition, the distribution region of the source 152 and the drain 154 is the same as the distribution region of the first region 120A. In other words, when not taking into account error margins in the fabricating process and such influences, the sum of the distribution region of the source 152 and the drain 154 is equal to the distribution region of the first region 120A, and the thickness of the gate insulating layer 120 at a part underneath the source 152 and the drain 154 (namely the first region 120A) is greater than the thickness of the gate insulating layer 120 at a part not underneath the source 152 and the drain 154 (namely the first region 120A). The gate insulating layer between the gate and drain of a conventional active element is equivalent only to the first insulating layer 122 of the present embodiment, and aside from the first insulating layer 122 that is between the gate 110 and the drain 154 of the active element 100, the present embodiment also has a second insulating layer 124. Therefore, the distance between the gate 110 and the drain 154 of the present embodiment is increased compared with conventional techniques, and the capacitance C_{GD} between the gate 110 and the drain 154 becomes smaller. According to the aforementioned equation (1), the feed-through voltage ΔV_{P} of the active element 100 of the present invention will correspondingly become smaller.

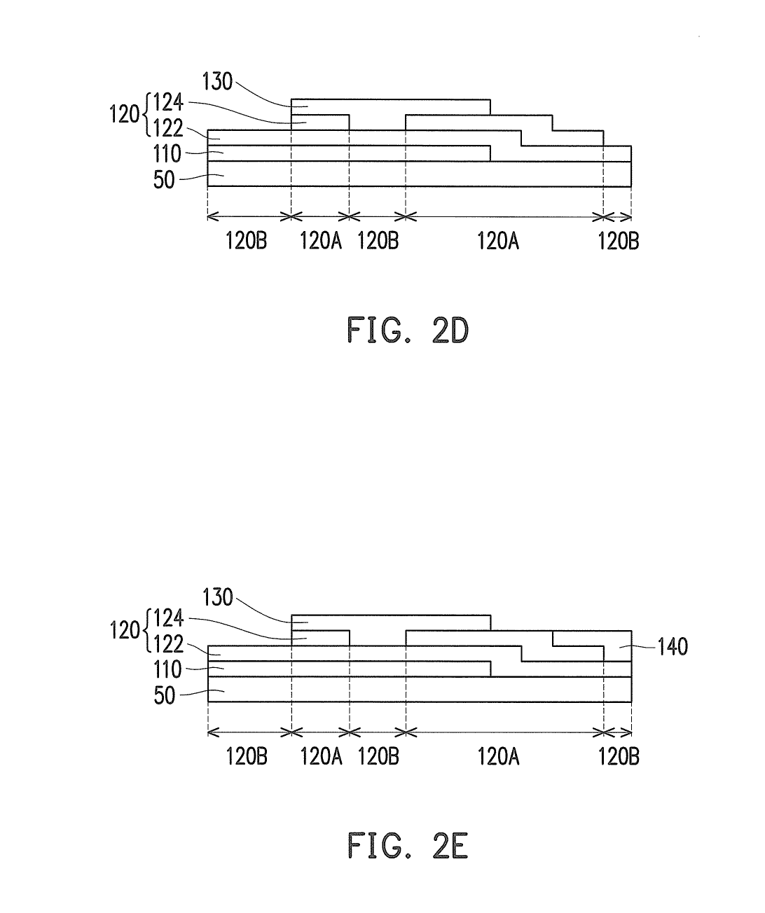

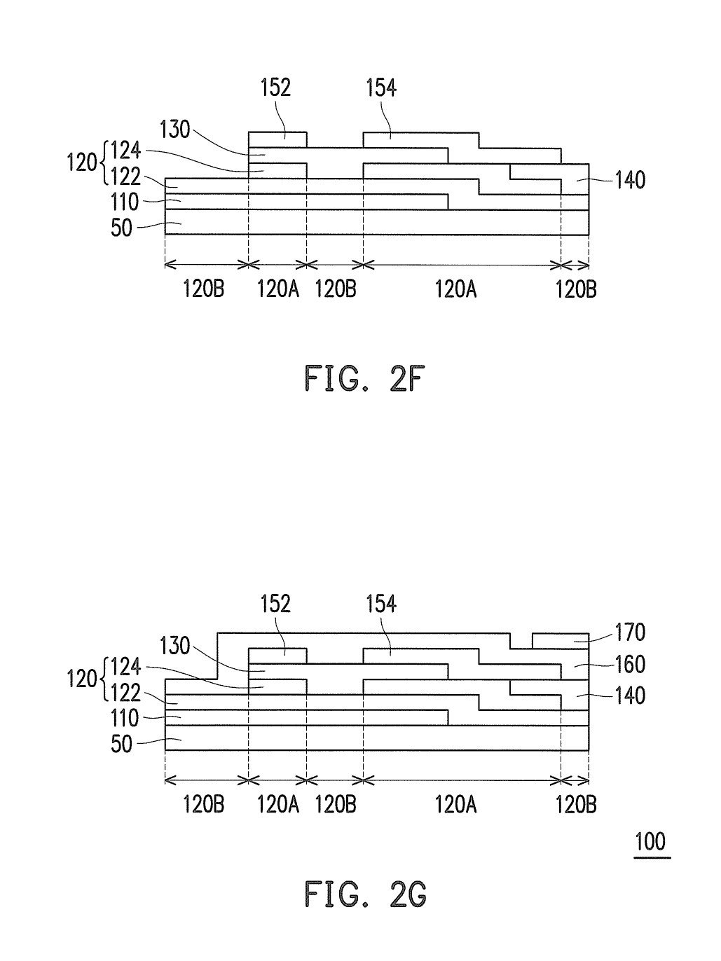

The Applicant performed simulations under conditions where the thickness of the second insulating layer 124 is 2000 Å and obtained the results in FIG. 3. A condition where the gate insulating layer is a uniform thickness is represented by the curve L12, and a condition where the gate insulating layer is as shown in FIG. 2F and the thickness of the second insulating layer 124 is 2000 Å is represented by the curve L14. From the curve L12, it can be seen when the resolution (represented in units of PPI, namely pixel per inch) of the applicable display device is increased, the capacitance C_{GD} will correspondingly increase. From the curve L14 it can be seen the capacitance C_{GD} still increases corresponding to the increases of the resolution, but compared to the curve L12 it can be seen that the capacitance G_{GD} has a 30% decrease. In addition, FIG. 4 shows a relationship between the feed-through voltage ΔV_{P} and the resolution of a display device obtained from a simulation under the same conditions as FIG. 3. The simulation conditions of a curve L16 of FIG. 4 and the curve L12 of FIG. 3 are the same, and the simulation conditions of a curve L18 of FIG. 4 and the curve L14 of FIG. 3 are the same. From a comparison of the curve L16 and the curve L18, it may be seen that the feed-through voltage ΔV_{P} of the curve L18 also has a 30% decrease. It can be seen, when the active element 100 of the present embodiment is used in a display device, the flickering condition on the screen may be significantly decreased, further enhancing the display quality.

At the same time, by the design of the present embodiment, a high resolution display device may still be fabricated under the conditions where a cheaper polysilicon is used as a material of the channel 130 of the active element 100, and a channel of a low temperature polysilicon material which requires using an expensive fabricating process does not need to be adopted. In addition, the area of the active element 100 of the present embodiment is adapted to still function properly when decreased, and thus assists in decreasing the border width of the display device. In addition, the distribution region of the source 152 and the drain 154 is the same as the distribution region of the first region 120A of the gate insulating layer 120, that is to say the source 152 and the drain 154 are formed using a photolithography process and the same photo mask may be used when forming the gate insulating layer 120. As for the present embodiment, the photo mask used for forming the second insulating layer 124 and the photo mask used for forming the source 152 and the drain 154 are the same. Therefore, although the gate insulating layer 120 fabricated in the present embodiment has a non uniform thickness, however it will not generate additional cost for purchasing and storing the photo mask. In addition, if the thickness of the entire layer of the gate insulating layer increases, according to the aforementioned equation (1), the pixel storage capacitance C_{ST} will decrease, and instead the feed-through voltage ΔV_{P} will increase again.

Furthermore, the channel 130 of the present embodiment has better carrier mobility. Carrier mobility is directly proportional with the magnitude of the electrical current and the length of the carrier moving path. Under the influence of the Hall effect, because the thickness of the channel 130 of the present embodiment at the second insulating layer 124 is greater compared to the thickness of conventional channels, after the carrier enters the upper layer of the channel 130 from the edge of the source 152, it will first move downwards to the lower layer of the channel 130, then move horizontally to the lower edge of the drain 154, and then move upwards to the upper layer of the channel 130 and enter the drain 154. Whereby, the channel 130 of the present embodiment has a longer carrier moving path, and may increase the carrier mobility of the channel 130.

Selectively, also as shown in FIG. 2G, an insulating layer 160 may be formed on the substrate 50. The insulating layer 160 covers each of the aforementioned elements formed. Then, a common electrode 170 is formed on the insulating layer 160. Using the electric field produced by a voltage difference between the pixel electrode 140 and the common electrode 170, the arrangement of the liquid crystal molecules may be controlled to achieve a display effect when using the active element 100 of the present embodiment with an LCD.

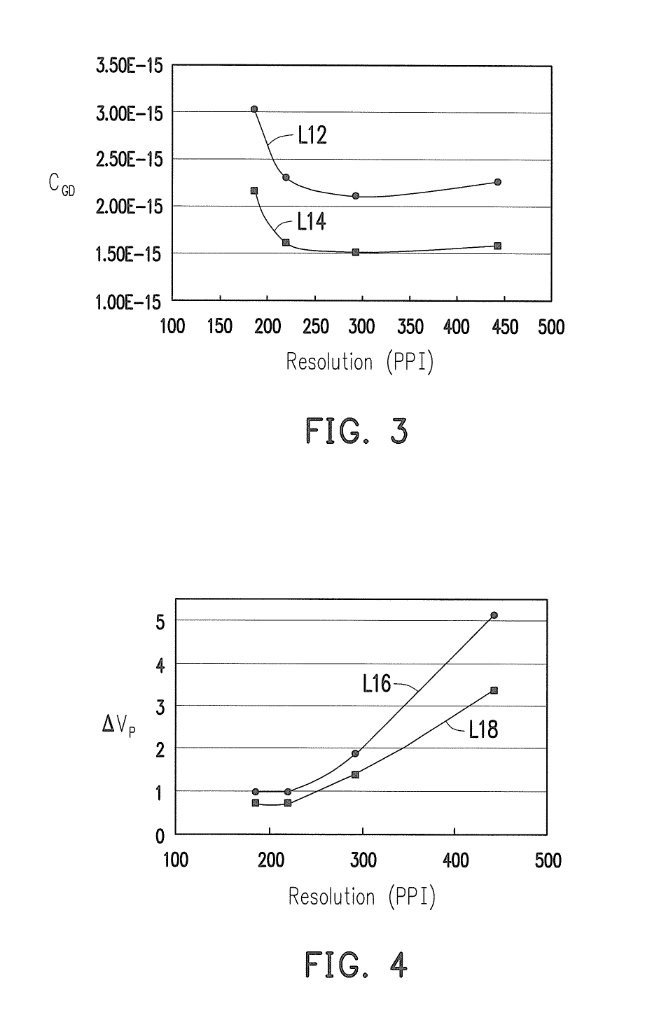

Next, referring to FIG. 5 and FIG. 2G, an example of using the active element 100 with an LCD will be described according to an embodiment of the invention, wherein FIG. 2G is a cross-sectional schematic view along the line I-I of FIG. 5. The active element 100 of the present embodiment includes the gate 110, the gate insulating layer 120 (only labeled in FIG. 2G), the channel 130, the source 152 and the drain 154. In addition, because the active element 100 of the present embodiment is used for a display device, it may include a scan line S20, a data line D20, the pixel electrode 140 and the common electrode 170, but the invention is not limited thereto. The gate 110 and the scan line S20, for example, are formed of the same material layer, and the data line D20, the source 152 and the drain 154, for example are formed of the same material layer. The gate 110 is directly connected with the scan line S20 or a part of the scan line S20, and the source 152 is directly connected with the data line D20 or a part of the data line D20. The present embodiment uses a Fringe Field Switching (FFS) LCD panel as an example, and at least one of the two, the pixel electrode or the common electrode may have a plurality of slits and a plurality of branches. In the present embodiment, the pixel electrode 140 is a massive electrode pattern without branches, and the common electrode 170 has an electrode pattern with a plurality of branches, but however in other embodiments the pixel electrode 140 and the common electrode 170 may be formed as other shaped patterns.

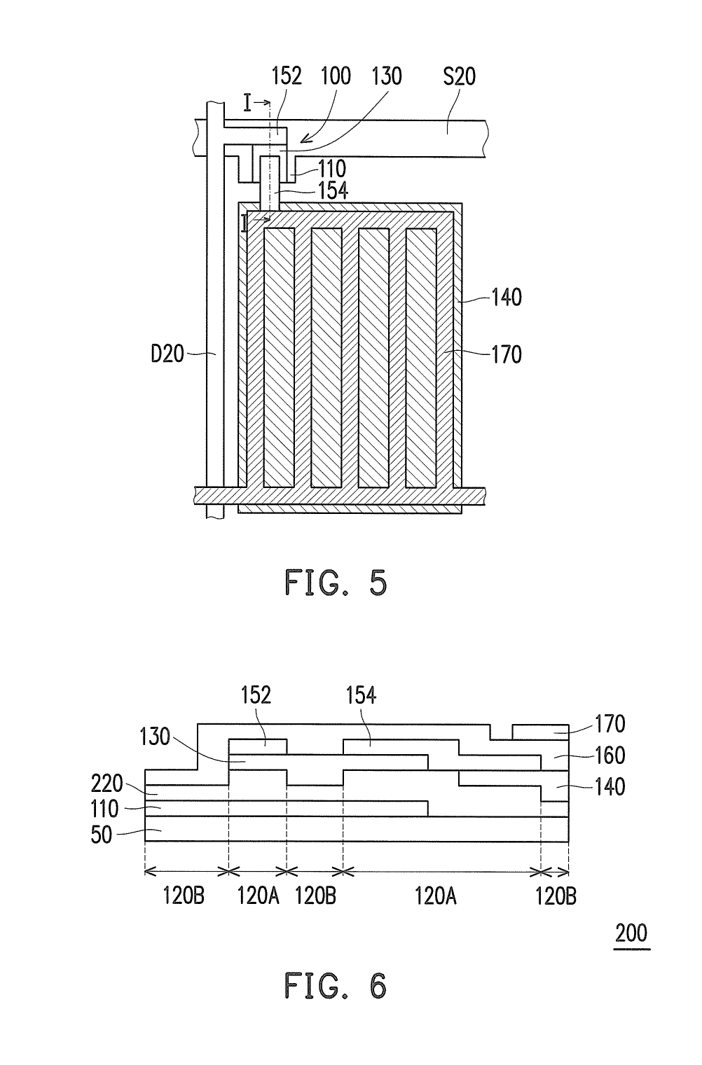

FIG. 6 is a cross-sectional schematic view illustrating an active element according to an embodiment of the invention. Referring to FIG. 6, the only difference between the active element 200 of the present embodiment and the active element 100 of FIG. 2G lies in a gate insulating layer 220 of the present embodiment is formed by a single material and a single photolithography process. Because the thickness of the gate insulating layer 220 is greater at the part underneath the source 152 and the drain 154, the active element 200 of the present embodiment similarly has a smaller capacitance C_{GD} between the gate 110 and drain 154, and the feed-through voltage ΔV_{P} correspondingly decreases. As can be seen, when using the active element 200 of the present embodiment with a display device, the flickering condition on the screen may be significantly decreased, further enhancing the display quality. For example, the gate insulating layer 220 of the present embodiment may be formed using a positive resist arranged with the photo mask used for forming the source 152 and the drain 154, and adjusting the exposure time. The gate insulating layer 220 may also be formed using a positive resist with a halftone photo mask.

In summary, in an active element and a fabrication method thereof of the invention, the thickness of a gate insulating layer underneath a source and a drain are increased, and therefore the capacitance between a gate and the drain may be decreased, further decreasing the feed-through voltage of the active element. In this way, an active element of better quality may be obtained, and when using with a display device, the flickering condition on the screen may be significantly decreased, further enhancing the display quality.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An active element, comprising:
a gate, disposed on a substrate having a surface;
a gate insulating layer, disposed on the surface of the substrate and covering the gate, wherein a normal projection on the surface of a portion of the gate insulating layer is within a normal projection on the surface of the gate, the portion of the gate insulating layer is divided into a first region and a second region outside the first region, and a thickness of the first region is constant in a normal direction of the surface, a thickness of the second region is constant in the normal direction of the surface, and the thickness of the first region is greater than the thickness of the second region;
a channel, disposed on the gate insulating layer; and
a source and a drain, respectively disposed on the gate insulating layer and separated from each other, wherein a normal projection on the surface of at least one portion of an edge of the source is within a normal projection on the surface of the first region, a normal projection on the surface of a portion of at least one edge of the drain is within the normal projection on the surface of the first region, and the channel contacts the source and the drain.

2. The active element as claimed in claim 1, wherein the gate insulating layer comprises:
a first insulating layer, located at the first region and the second region, wherein a thickness of the first insulating layer is constant; and
a second insulating layer, located at the first region, wherein a thickness of the second insulating layer is constant.

3. The active element as claimed in claim 2, wherein a material of the first insulating layer is different from a material of the second insulating layer.

4. The active element as claimed in claim 1, wherein a material of the gate insulating layer is a single material.

5. The active element as claimed in claim 1, further comprising a pixel electrode electrically connected with the drain.

6. The active element as claimed in claim 1, wherein a material of the channel is amorphous silicon.

7. A fabricating method of an active element, comprising the following steps:
forming a gate on a substrate having a surface;
forming a gate insulating layer on the surface of the substrate and covering the gate, wherein a normal projection on the surface of a portion of the gate insulating layer is within a normal projection on the surface of the gate, the portion of the gate insulating layer is divided into a first region and a second region outside the first region, and a thickness of the first region is constant in a normal direction of the surface, and a thickness of the second region is constant in a normal direction of the surface, and the thickness of the first region is greater than the thickness of the second region; and
forming a channel, a source and a drain on the gate insulating layer, wherein the source and the drain are separated from each other, and a normal projection on the surface of at least one portion of an edge of the source is within a normal projection on the surface of the first region, a normal projection on the surface of a portion of at least one edge of the drain is within the normal projection on the surface of the first region, and the channel contacts the source and the drain.

8. The fabricating method of an active element as claimed in claim 7, wherein the step of forming the gate insulating layer comprises:
forming a first insulating layer at the first region and the second region, wherein a thickness of the first insulating layer is constant; and
forming a second insulating layer at the first region, wherein a thickness of the second insulating layer is constant.

9. The fabricating method of an active element as claimed in claim 8, wherein a photo mask used for forming the second insulating layer and a photo mask used for forming the source and the drain are the same.

10. The fabricating method of an active element as claimed in claim 7, wherein the gate insulating layer is formed by a single photolithography process.
